(19) United States
(12) Patent Application Publication
(10) Pub. No.: US 2014/0367671 A1
(43) Pub. Date: Dec. 18, 2014

(54) ORGANIC ELECTROLUMINESCENT DEVICE AND METHOD FOR PRODUCING SAME

(71) Applicant: Toppan Printing Co., Ltd., Tokyo (JP)

(72) Inventor: Hiroshi TADA, Tokyo (JP)

(21) Appl. No.: 14/474,840

(22) Filed: Sep. 2, 2014

Related U.S. Application Data
(63) Continuation of application No. PCT/JP2013/000879, filed on Feb. 18, 2013.

(30) Foreign Application Priority Data
Mar. 15, 2012 (JP) 2012-058531

(51) Int. Cl. H01L 51/50; H01L 51/00

(52) U.S. Cl. CPC H01L 51/5024; H01L 51/5056; H01L 51/0004
USPC 257/40

(57) ABSTRACT

The present invention attempts to improve coating processes used to produce organic EL devices, such as that an under layer is dissolved by a coating solution and efficiency and stability are poor. The present invention provides an organic EL device equipped with at least a first electrode formed on a substrate, a light emission medium layer containing at least an organic light emission layer, and a second electrode so formed as to face the first electrode so that the light emission medium layer can be sandwiched between the first electrode and the second electrode, wherein at least the organic light emission layer and a hole-transport layer adjacent to the organic light emission layer are contained in the light emission medium layer, and at least a low-molecular-weight hole-transport material and a matrix polymer having insulation properties and weight average molecular weight of about 200,000 to about 50,000,000 inclusive are contained in the hole-transport layer.

### CROSS-REFERENCE TO RELATED PATENT APPLICATIONS

This application is a continuation application filed under 35 U.S.C. §111(a) claiming the benefit under 35 U.S.C. §§120 and 365(c) of PCT International Application No. PCT/JP2013/000879 filed on Feb. 18, 2013, which is based upon and claims the benefit of priority of Japanese Application No. 2012-058531 filed on Mar. 15, 2012, the entire contents of both are hereby incorporated by reference in their entireties.

### BACKGROUND OF THE INVENTION

1. Technical Field

The present invention relates to an organic EL device using electroluminescence (EL, below) and a method for producing the same.

2. Background Art

An organic EL device is one having an organic emission layer between a pair of electrodes facing each other, and emitting light by applying a current to the organic emission layer.

FIG. 3 show a schematic view of a general organic electroluminescent device 300. One pixel (picture element) 301 consists of each subpixel 302 of R (red), G (green), B (blue) of three primary colors. In the subpixel 302, an organic EL device of the corresponding emission color is formed, and with an active-matrix drive, further a thin film transistor (hereinafter also referred to as TFT) is formed.

Generally, as a substrate for a display, substrates can be used where a patterned insulating material, such as photosensitive polyimide, is formed into a separator wall to separate each subpixel 302. The separator wall pattern is formed to cover a transparent electrode deposited as an anode, and the separator wall pattern defines each subpixel region.

Thereafter, a hole-injection layer is formed on the transparent electrode and the separator wall pattern. As for the methods for forming the hole-injection layer for injecting hole carriers, there are two types: a dry film formation method and a wet film formation method. If the wet film formation method is used, generally, derivatives of polythiophene dispersed in water, and the like, are used. A hole-transport layer is sometimes formed on the hole-injection layer.

The methods for forming the organic emission layer also include two types, a dry film formation method and a wet film formation method. If a vacuum vapor deposition method capable of forming a uniform film easily is used, there is a need for patterning by using a finely patterned mask. Therefore, a large substrate and fine patterning is very difficult.

On the other hand, there is a possible method where a polymeric material or a low-molecular-weight material is dissolved in a solvent to be a coating liquid, and a thin film is formed with this by a wet film formation method. In a case where a light emission medium layer having the organic emission layer is formed by a wet film formation method using the coating liquid of a polymeric material or a low-molecular-weight material, the layer configuration is generally a two-layered configuration where the hole-transport layer and the organic emission layer are stacked in order from the anode side. At this time, in order to form a color device, the organic emission layer can be formed by coating separately with each organic emission ink where an organic light emission having a respective emission color among red (R), green (G) and blue (B) is dissolved or stably dispersed in a solvent (PTLs 1 and 2).

If the organic layer is formed by a vacuum vapor deposition, a large area or high fineness is difficult as described above, and the equipment cost is high. On the other hand, with a wet film formation method, the equipment cost is comparatively low because no vacuum equipment is used, and there is an advantage of increasing the area because no mask is used.

For pattern formation by a wet film formation method, pattern formation according to an ink jet method, a printing method and a nozzle printing method has been suggested. The ink jet method is a method where an emission layer material dissolved in a solvent is injected from ink jet nozzles onto a substrate, followed by drying on the substrate, thereby obtaining a desired pattern (PTL 3).

For increasing efficiency and lifetime, the organic EL device is made have a laminated structure to separate functions. However, a wet film formation method has a problem that lamination of organic films is difficult. The reason is that, when an organic film is further formed on another organic film, the organic film of the under layer dissolves. Although choosing a solvent which does not dissolve the organic film of the under layer is one way, combinations of materials of the under layer and the organic materials coating it are limited. This narrows the range of choice for organic materials to lower device properties (PTLs 4 and 5).

Also, a cross-linkable material is used for the under layer, and made cross-linked after depositing, thereby it can be insolubilized. In this case, there is concern that introducing a highly reactive cross-linking group causes adverse effect on device characteristics, and synthesis of the materials becomes difficult and costly.

On the other hand, a method for making the laminated structure by forming with a wet method using a mixed solvent consisting of a good solvent and a poor solvent is disclosed. With this method, however, there has been a problem that the good solvent dissolves the under layer. Moreover, if the ratio of the good solvent is reduced, the solubility of the ink decreases, therefore films can be formed only to be at thin thickness (PTL 6).

There is disclosed a method for preventing the dissolution of the under layer by raising the temperature of the film surface to be equal to or larger than the boiling point of the solvent during coating. With this method, however, there has been some problems that a non-uniform deposition is likely to occur in the coating film because the solvent dries extremely fast, and further, film thickness distribution in plane is widely varied because leveling is not performed (PTL 7).

### CITATION LIST

### Patent Literature

[PTL 1] Japanese Patent Application Publication No. 2001-93668
[PTL 2] Japanese Patent Application Publication No. 2001-155858
[PTL 3] Japanese Patent Application Publication No. H10-12377
[PTL 4] Japanese Patent Application Publication No. 2002-299061
[PTL 5] Japanese Patent Application Publication No. 2002-319488
[PTL 6] Japanese Patent Application Publication No. 2005-259523
[PTL 7] Japanese Patent Application Publication No. 2006-172987

### SUMMARY OF THE INVENTION

### Technical Problem

The invention has been made so as to attempt to improve or solve at least some of the problems described above. That is, in the method for producing an organic EL device, coating methods are excellent at productivity, but there has been a problem that a coating liquid dissolves an under layer, therefore coating methods have lacked efficiency and stability. The invention provides a method for producing a more high-efficient and a more long-lived organic EL device without dissolving the hole-transport layer at a coating surface, even if this is solved and the formation is performed by coating.

### Improvement or Solution to Problem

As means for attempting to improve or even solving the above problems, a first embodiment of the present invention is an organic electroluminescent device, wherein: the organic electroluminescent device has a first electrode formed on a substrate, a light emission medium layer having at least an organic emission layer, and a second electrode formed to face the first electrode with the light emission medium layer sandwiched therebetween; the light emission medium layer has at least an organic emission layer and a hole-transport layer adjacent to the organic emission layer; and the hole-transport contains at least a low-molecular weight hole-transport material and a matrix polymer having insulation properties and weight-average molecular weight of from not smaller than 200 thousand to not larger than 50 million.

A second embodiment of the present invention is the organic electroluminescent device defined in the first embodiment of the present invention, characterized in that a separator wall is formed to separate a light emission region.

A third embodiment of the present invention is the organic electroluminescent device defined in the first or second embodiment of the present invention, characterized in that the weight-average molecular weight of the matrix polymer having insulation properties is from not smaller than 1 million to not larger than 50 million.

A fourth embodiment of the present invention is the organic electroluminescent device defined in any one of the first to third embodiments of the present invention, characterized in that the organic emission layer contains at least a low-molecular-weight light emission material and a matrix polymer having insulation properties and a weight-average molecular weight of from not smaller than 200 thousand to not larger than 50 million.

A fifth embodiment of the present invention is the organic electroluminescent device defined in the fourth embodiment of the present invention, characterized in that the organic emission layer contains at least the low-molecular-weight light emission material and the matrix polymer having insulation properties and a weight-average molecular weight of from not smaller than 1 million to not larger than 50 million.

A sixth embodiment of the present invention is the organic electroluminescent device defined in any one of the first to fifth embodiments of the present invention, characterized in that the hole-transport layer and the organic emission layer contain the same type of the matrix polymer having insulation or insulating properties.

A seventh embodiment of the present invention is the organic electroluminescent device defined in any one of the first to sixth embodiments of the present invention, characterized in that the hole-transport layer and the organic emission layer are formed by a coating method.

An eighth embodiment of the present invention is the organic electroluminescent device defined in the seventh embodiment of the present invention, characterized in that the substrate is heated in a step where the organic emission layer is formed by coating.

A ninth embodiment of the present invention is the organic electroluminescent device defined in the eighth embodiment of the present invention, characterized in that a temperature for heating the substrate is equal to or smaller than the boiling point of an solvent of an ink forming the organic emission layer.

A tenth embodiment of the present invention is the organic electroluminescent device defined in any one of the first to ninth embodiments of the present invention, characterized in that a step for applying the organic emission layer is by a nozzle printing method.

An eleventh embodiment of the present invention is the organic electroluminescent device defined in any one of the first to ninth embodiments of the present invention, characterized in that a step for applying the organic emission layer is by a relief printing method.

### Advantageous Effects of Invention

According to the combination of the low-molecular-weight hole-transport material and huge molecular-weight polymer having insulation properties, even if a light emission layer is formed by coating on a hole-transport layer configuring an EL device, the hole-transport layer is not eroded and while maintaining performance. Accordingly, a more simple and more highly productive coating method can be used, and a more highly efficient and more long-lived organic EL device can be obtained.

### BRIEF DESCRIPTION OF THE DRAWINGS

FIG. 1 is a schematic view showing an embodiment of an organic EL device of the present invention.

FIG. 2 is showing an embodiment of a TFT substrate with a separator wall, which is usable in the present invention.

FIG. 3 is a schematic view showing a general organic EL device.

### DETAILED DESCRIPTION OF THE PREFERRED EMBODIMENTS

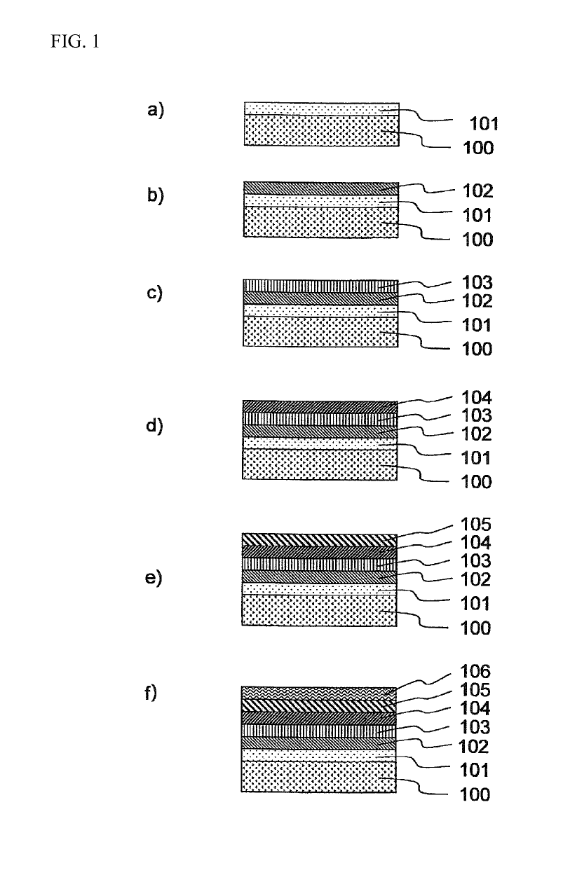

Embodiments for carrying out the present invention are now described, referring to the drawings. FIG. 1 shows an example of an embodiment of an organic EL device of the present invention. At first, a) a first electrode 101 is formed on a substrate 100. Next, b) a hole-injection layer 102 is formed on the first electrode 101. Sequentially, c) a hole-transport layer 103 is formed on the hole-injection layer 102 by a coating method. The hole-transport layer 103 contains at least a hole-transport material and a matrix polymer whose weight-average molecular weight is about 200 thousand or more. Next, d) an organic emission layer 104 is formed on the hole-transport layer 103 by a coating method.

With organic devices, most organic materials used such as in the hole-transport layer 103, the organic emission layer 104 and an electron-transport layer 105 are similar in solubility. Accordingly, for example, when the organic emission layer 104 is formed by coating after forming the hole-transport layer 102, the hole-transport layer 103 is eluted into a solvent of an ink of the organic emission layer material. Therefore, there occurs a problem that the hole-transport layer 103 is eluted, thereby reducing thickness thereof.

In the present invention, fluidity of the organic material contained in the hole-transport layer 103 is lowered by providing the hole-transport layer 103 with the matrix polymer, thereby preventing the hole-transport layer 103 and the organic emission layer 104 from mixing when the hole-transport layer 103 is coated with the organic emission layer 104. For lowering fluidity sufficiently in solution state, it is essential that the matrix polymer has a weight-average molecular weight of from not less than about 200 thousand to not larger than about 50 million. Further, it is preferred that the weight-average molecular weight of the matrix polymer is a million or more. Generally, mixing the matrix polymer with the hole-transport layer 103 causes hole mobility to lower. However, if the weight-average molecular weight of the matrix polymer is a million or more, the effect of decrease in fluidity can be obtained even when a mixing ratio of the matrix polymer is low. Therefore, the mobility can be prevented from lowering. If the weight-average molecular weight of the matrix polymer is over about 50 million, it is insoluble in a solvent.

It is essential that the matrix polymer contained in the hole-transport layer 103 has insulation properties. Insulation properties means there is relatively no conductive properties and relatively no charge transport properties. If the matrix polymer has conductive properties or charge transport properties, carriers are injected not only in a low-molecular-weight hole-transport material but also in the matrix polymer, which causes a deterioration of characteristics.

The hole-transport layer 103 contains a low-molecular-weight hole-transport material. A low-molecular-weight hole-transport material has a higher possibility of material design than a polymer material has, therefore the band gap can be widened easily. Accordingly, excitation blocking properties and electron blocking properties are high, which causes high device efficiency. Also, durability is high.

It is preferred that the mixing ratio of the matrix polymer contained in the hole-transport layer 103 is about 5%-70%, more preferably about 10%-50%. The reason is that if the mixing ratio is too low, then the effect of lowering fluidity cannot be obtained sufficiently, and that if the mixing ratio is too high, then the hole-transport ability of the hole-transport layer is significantly lowered. It is preferred that the organic emission layer 104 contains at least a low-molecular-weight light emission material and a matrix polymer whose molecular-weight is about 200 thousand or more. The fluidity of the materials contained in the organic emission layer is lowered by providing the matrix polymer, thereby the hole-transport layer 103 and the organic emission layer 104 can be prevented from mixing when the hole-transport layer 103 is coated with the organic emission layer 104.

Further, it is preferred that the weight-average molecular weight of the matrix polymer is about a million or more. Generally, mixing the matrix polymer with the organic emission layer 104 causes hole mobility and electron mobility to lower. However, if the weight-average molecular weight of the matrix polymer is about a million or more, then the mobility can be prevented from lowering, because the effect of decrease in fluidity can be obtained even when a mixing ratio of the matrix polymer is low. In addition, it is preferred that the hole-transport layer 103 and the organic emission layer 104 contain the same matrix polymer. If the hole-transport layer 103 and the organic emission layer 104 contain the same matrix polymer, then bonding of the interfaces of the hole-transport layer 103 and the organic emission layer 104 can be improved, so that injection of the carrier is improved.

It is preferred that the mixing ratio of the matrix polymer contained in the organic emission layer 104 is about 5%-70%, more preferably about 10%-50%. The reason is that if the mixing ratio is too low, the effect of lowering fluidity cannot be obtained sufficiently, and that if the mixing ratio is too high, the charge-transport ability of the organic emission layer is significantly lowered and luminous efficiency is lowered. It is preferred to heat the substrate in a step for forming the organic emission layer 104 by coating. Heating the substrate accelerates drying of the solvent, which can prevent the hole-transport layer 103 and the organic emission layer 104 from mixing during forming the organic emission layer 104. It is preferred that the substrate heating temperature at this time is equal to or less than the boiling point of the solvent of the ink forming the organic emission layer 104. If heating is carried out at or over the boiling point, a non-uniform deposition is likely to occur in the coating film because the solvent dries extremely fast, and further, film thickness distribution in plane is widely varied because leveling is not performed.

Next, e) the electron-transport layer 105 is formed on the organic emission layer 104, for example, by a vacuum vapor deposition method. Sequentially, f) a second electrode 106 is formed on the electron-transport layer 105. After the above steps, the organic electroluminescent device is formed.

In the organic EL device, it is preferred that a separator wall is formed such as to separate the light emission regions. The formation of the separator wall can prevent the solution from flowing along the in-plane direction during forming the organic emission layer by coating, therefore the organic emission layer 104 is formed more uniformly.

The organic EL device according to the present invention can be used in any of a passive-matrix drive type and an active-matrix drive type.

The present invention can be applied such as to the device 300 and lighting devices.

Hereinafter, detailed configurations of examples of the present invention are described.

### <Substrate>

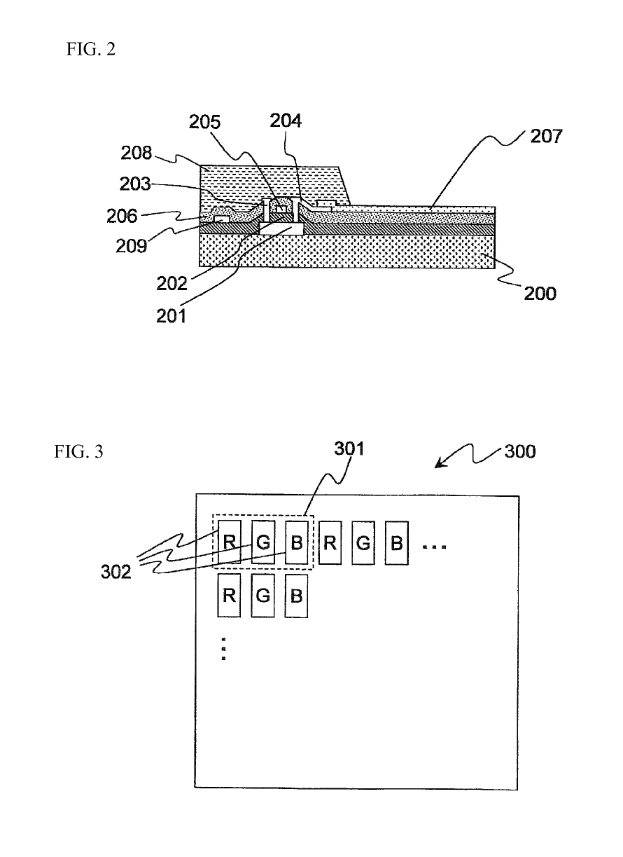

Although the substrate 200 used in embodiments of the present invention may be ones that can support the organic EL device, in an active-matrix type, a TFT substrate where thin-film transistors are formed is used. FIG. 2 is an example of a TFT substrate with the separator wall, which can be used for the present invention. TFTs and a pixel electrode (the first electrode) 207 are provided, and TFTs and the pixel electrode 207 are electrically connected to each other.

The TFTs and the active-matrix type organic EL device formed thereon are supported by a support. As the support, there can be used any materials as long as the substrate has mechanical strength, insulation properties and excellent dimension stability.

For example, there can be used glass, silica, plastic films or sheets such as of polypropylene, polyethersulfone, polycarbonate, cycloolefin polymer, polyarylate, polyamide, polymethylmethacrylate, polyethylene terephthalate and polyethylene naphthalate, translucent substrates formed by stacking, on the plastic film or sheet, one or more layer of metal oxide such as silicon oxide and aluminum oxide, metal fluoride such as aluminum fluoride and magnesium fluoride, metal nitride such as silicon nitride and aluminum nitride, metal oxynitride such as silicon oxynitride, and polymer resin film such as of acrylic resin, epoxy resin, silicon resin and polyester resin, non-translucent substrates formed by stacking a metal film such as of aluminum, copper, nickel and stainless steel on a metal foil, a sheet or a plate such as of aluminum and stainless steel, or the above plastic film or sheet, or the like.

Translucency may be chosen depending on which surface the light is extracted from. It is preferred that the support made from these materials is subjected to a moisture proof treatment or a hydrophobization treatment, such as forming an inorganic film or coating with a fluorine resin, for preventing water from entering inside of the organic EL device. Especially, in order to prevent water from invading the organic emission layer, it is preferred that the moisture content in the support and the gas transmission coefficient are lowered.

As the thin film transistor that is provided on the support, there may be used a publicly known thin film transistor. Specifically, mainly, there can be a thin film transistor having an active layer 201 where source/drain regions and a channel region are formed, a gate insulator layer 202 and a gate electrode 205. The structure of the thin film transistor is not limited specifically, and can include, for example, a staggered type, an inverted staggered type, a top gate type and a coplanar type.

The active layer 201 is not limited especially, for example, can be formed from inorganic semiconductor materials such as amorphous silicon, polycrystalline silicon, microcrystalline silicon or cadmium selenide, metal oxide semiconductor materials such as ZnO or IGZO, or organic semiconductor materials such as thiophene oligomer or poly(p-phenylenevinylene).

As these active layer, for example, there can be:

a method where amorphous silicon is stacked by a plasma CVD method, and ion-doped;

a method where amorphous silicon is stacked by a LPCVD method using SiH₄ gas, and amorphous silicon is crystallized by a solid-phase growth method to obtain polysilicon, thereafter subjecting to ion-doping by an ion implantation method;

a method where amorphous silicon is stacked by a LPCVD method using Si₂H₆ gas or by a PECVD method using SiH₄ gas, followed by annealing by a laser such as excimer laser to make amorphous silicon crystallize, thereby obtaining polysilicon, thereafter subjecting ion-doping by a ion-doping method (low temperature process); and

a method where polysilicon is stacked by a low pressure CVD method or a LPCVD method, followed by thermally-oxidizing to form a gate insulator layer at 1000° C. or more, and forming a gate electrode of n⁺ polysilicon thereon, thereafter subjecting ion-doping by an ion implantation (high temperature process).

As the gate insulator layer 202, there can be used the ones generally used as gate insulator layers, for example, SiO₂ formed by a PECVD method, a LPCVD method and the like, or SiO₂ obtained by thermal-oxidizing polysilicon film can be used.

As the gate electrode 205, there can be used the ones generally used as gate electrodes, there can be, for example, metal such as aluminum and copper; high melting point metal such as titanium, tantalum and tungsten; polysilicon; silicide of high melting point metal; polycide; or the like.

The thin film transistor may have a single-gate structure, a double-gate structure, or a multi-gate structure having three or more gate electrodes. It may have a LDD (Lightly Doped Drain) structure, or an offset structure. Further, two or more thin film transistors may be disposed in one pixel.

In the display device of the present invention, the thin film transistor needs to be connected such as to function as a switching device of the organic EL device, a drain electrode 204 of the transistor and the pixel electrode of the organic EL display device are electrically connected to each other.

### <Pixel Electrode>

The pixel electrode (first electrode) 207 is formed on the substrate, and patterned as necessary. As the materials of the pixel electrode, there may be used any one of a single layer and a laminate of metal complex oxide such as ITO (indium tin complex oxide), indium zinc complex oxide and zinc aluminum complex oxide, metal materials such as gold and platinum, and a fine particle dispersed film where fine particles of these complex oxides or metal materials are dispersed in epoxy resin, acrylic resin or the like.

It is preferred that a material whose work function is high, such as ITO, is chosen, when the pixel electrode 207 is used as an anode. With a so-called bottom emission structure where the light is extracted from a lower side, there is a need for choosing a material having translucency. As the methods for forming the pixel electrode, depending on materials, there can be used dry film-formation methods such as a resistance heating vapor deposition method, an electron beam vapor deposition method, a reactive vapor deposition method, an ion plating method and a sputtering method, and wet film-formation methods such as a gravure printing method and a screen printing method. As the patterning methods of the pixel electrode, depending on materials and film-formation methods, there can be used existing patterning methods, such as a mask vapor deposition method, a photolithographic method, a wet etching method and a dry etching method. In the present invention, the photolithographic method is preferred.

### <Separator Wall>

The separator wall 208 is formed to separate each light emission region corresponding to a respective pixel. The separator wall is formed to form an opening for holding a solution dissolving the organic material when the organic layer is formed by a coating method.

As the methods for forming the separator wall 208, there can be a method where an inorganic film is formed uniformly on a base, and masked with a resist, thereafter subjecting to dry etching, and another method where a light-sensitive resin is stacked on a base, thereafter forming a predetermined pattern by a photolithography method. Preferable height of the separator wall is 0.1 μm-10.0 μm, more preferably approximately 0.5 μm-4.0 μm. If it is too high, then the formation of electrode and sealing are hindered. If it is too low, colors of adjacent pixels are mixed when the light emission medium layer is formed. As the separator wall, a light-sensitive resin can be used favorably. As the light-sensitive resins, both of positive resist and negative resist are suitable, specifically, there can be polyimide-based, acrylic resin-based and novolak resin-based light-sensitive resins. An water repellent agent can be added as needed, or repellency against an ink can be provided by irradiating plasma or UV after the formation.

### <Organic EL Device>

An example of the organic EL devices has a configuration where the hole-injection layer 102, the hole-transport layer 103, the organic emission layer 104 and the electron transport layer 105, which serve as a light emission medium layer, are provided on the first electrode 101 in series, and further the second electrode 106 is formed. A part of these layers sandwiched between the electrodes can be omitted, or a layer such as a hole-block layer can be added thereto, properly chosen from publicly known ones.

### <Hole-Injection Layer>

The hole-injection layer 102 has a function for injecting holes from the first electrode. It is preferred that the hole-injection layer 102, as a physical property, has a work function equal to or more than the work function of the pixel electrode 207. The reason is for performing the hole-injection from the pixel electrode efficiently. Although it differs depending on materials of the pixel electrode 207, from not less than 4.5 eV to not more than 6.5 eV can be used. If the pixel electrode is ITO or IZO, from not less than 5.0 eV to not more than 6.0 eV can be used favorably. It is preferred that the resistibility of the hole-injection layer, in a state of a thickness of 30 nm or more, is 1×10³-2×10⁶ Ω·m, more preferably 5×10³-1×10⁶ Ω·m. With the bottom emission structure, since the emission light is extracted from the pixel electrode side, if the light permeability is low, the extraction efficiency is lowered. Therefore, it is preferred that the light permeability is 75% or more in overall average of wavelength range of visible light, and 80% or more can be used favorably.

As the materials forming the hole-injection layer 102, there can be used, for example, polymer materials such as polyaniline, polythiophene, polyvinyl carbazole, a mixture of poly(3,4-ethylenedioxythiophene) and polystyrene sulfonate, or the like. Aside from these, conductive polymers whose electrical conductivity is from not smaller than 10⁻² S/cm to not larger than 10⁻⁶ S/cm can be used preferably. Polymer materials can be used in a film-formation step by a wet method. Therefore, it is preferred that polymer materials are used when the hole-injection layer is formed. Such a polymer material is dispersed or dissolved with water or solvent to be used as a dispersion or a solution.

If an inorganic material is used as the hole-transport material 103, there can be used Cu₂O, Cr₂O₃, Mn₂O₃, FeO_{X} (X˜0.1), NiO, CoO, Bi₂O₃, SnO₂, ThO₂, Nb₂O₅, Pr₂O₃, Ag₂O, MoO₂, ZnO, TiO₂, V₂O₅, Nb₂O₅, Ta₂O₅, MoO₃, WO₃, MnO₂ or the like.

As the methods for forming the hole-injection layer 102, a collective formation can be performed at the whole display region on the pixel electrode 207 with simple methods such as a slit coat method, a spin coat method, a die coat method, a dipping method, a blade coat method or a spray method. Also, there can be used existing methods including wet film-formation methods such as a relief printing method, a gravure printing method or a screen printing method.

When the hole-injection layer 102 is formed, an ink (liquid material) where the above hole-transport material is dissolved in water, an organic solvent or a mixture solvent thereof is used. As the organic solvent, there can be used toluene, xylene, anisole, mesitylene, tetralin, acetone, methyl ethyl ketone, methyl isobutyl ketone, cyclohexanone, methanol, ethanol, isopropyl alcohol, ethyl acetate, butyl acetate or the like. Further, a surface acting agent, an antioxidant, a viscosity modifier, an ultraviolet absorber or the like may be added to the ink.

If the hole-injection layer 102 is an organic material, it is formed by using a dry process such as a resistance heating vapor deposition method, an electron beam vapor deposition method, a reactive vapor deposition method, an ion plating method, a sputtering method or the like.

### <Hole-Transport Layer>

The above hole-transport layer 103 is stacked between the organic emission layer 104 and the hole-injection layer 102, and has a function for improving the emission lifetime of the device.

As the materials of the hole-transport layer 103, there can be used low-molecular-weight materials favorably. For example, it can include aromatic amine, triarylamines such as (triphenylamine)dimer derivative (TPD), (α-naphthyldiphenylamine)dimer (α-NPD), [(triphenylamine)dimer]spiro dimer (Spiro-TAD), TPTE shown in Chem. 1 or TPT1 shown in Chem. 2, star-burst amines such as 4,4′,4″-tris[3-methylphenyl(phenyl)amino]triphenylamine (m-MTDATA), 4,4′,4″-tris[1-naphthyl(phenyl)amino]triphenylamine (1-TNATA), oligothiophenes such as 5,5′-α-bis-{4-[bis(4-methylphenyl)amino]phenyl}-2,2′:5′,2′-α terthiophen (BMA-3T), or the like. In the present invention, however, it is not limited to these.

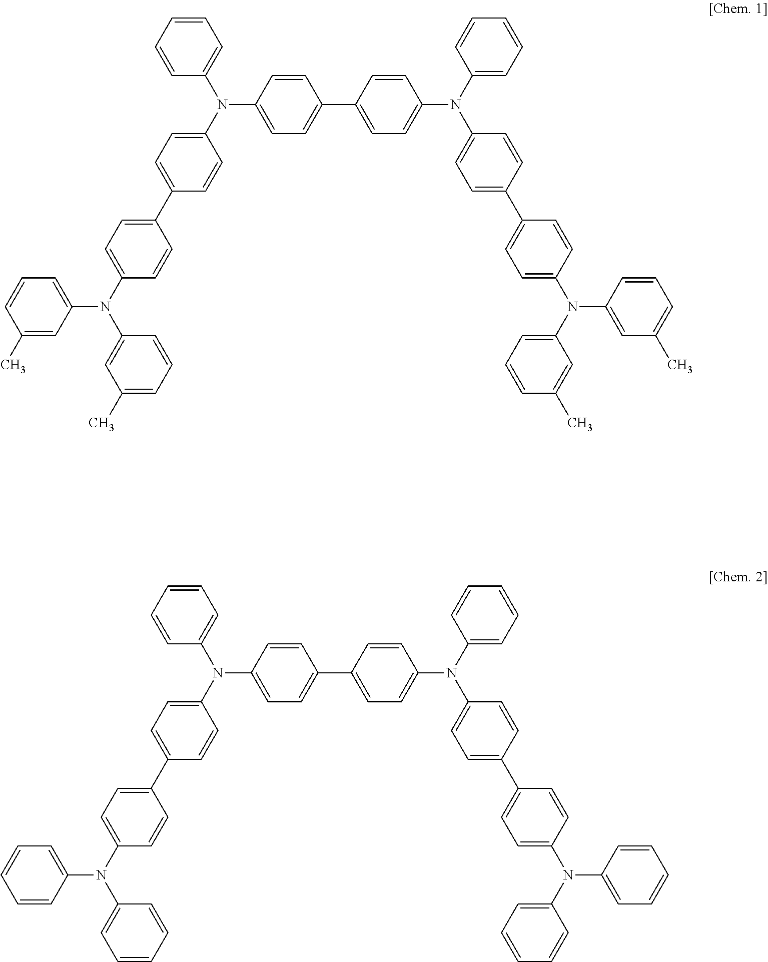 [SMILES: Cc1cccc(N(c2ccc(-c3ccc(N(c4ccccc4)c4ccc(-c5ccc(N(c6ccccc6)c6ccc(-c7ccc(N(c8cccc(C)c8)c8cccc(C)c8)cc7)cc6)cc5)cc4)cc3)cc2)c2cccc(C)c2)c1 ; c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

The hole-transport layer 103 contains a matrix polymer whose weight-average molecular weight is from not less than 200 thousand to not more than 50 million. As the matrix polymers, there can be used favorably, for example, polycarbonate, polystyrene, polymethylmethacrylate, polypropylene, polyethersulfone, cycloolefin polymer, polyarylate, polyamide, polyethylene terephthalate or polyethylene naphthalate.

These organic materials are dissolved or dispersed stably in a solvent to form inks of the organic hole-transport layer 103. As the solvents for dissolving or dispersing organic hole-transport materials, there may be a single or a mixed solvent of toluene, xylene, acetone, anisole, methyl ethyl ketone, methyl isobutyl ketone, cyclohexanone and the like. Of these, aromatic organic solvent such as toluene, xylene or anisole are favorable in view of the solubility of the organic hole-transport materials. Further, a surface acting agent, an antioxidant, a viscosity modifier, an ultraviolet absorber or the like may be added to the organic hole-transport layer ink, as needed.

As these hole-transport layer materials, it is preferred that a material having the work function equal to or more than the work function of the hole-injection layer 103 is chosen, more preferably the work function is equal to or less than that of the organic emission layer 104. The reason is for preventing the formation of any unneeded injection barrier when carriers are injected from the hole-injection layer 103 to the organic emission layer 104. In addition, for obtaining an effect of trapping electrons which have not contribute the light emission from the organic emission layer 104, it is preferred that the band gap is 3.0 eV or more, more preferably 3.5 eV or more can be used favorably.

As the method for forming the hole-transport layer 103, collective formation at the whole display region on the pixel electrode 207 can be carried out using simple methods such as a slit coat method, a spin coat method, a die coat method, a dipping method, a blade coat method or a spray method. Also, there can be used existing methods including wet film-formation methods such as a relief printing method, an ink jet method, a nozzle printing method, a gravure printing method or a screen printing method.

### <Organic Emission Layer>

After forming the hole-transport layer, the organic emission layer 104 is formed. The organic emission layer 104 is a layer which emits light by the current flowing therethrough, and is formed to cover the hole-transport layer 103 in a case where display light emitted from the organic emission layer is monochromatic. On the other hand, in order to obtain polychromatic display light, it can be subjected to patterning as needed, thereby being able to use it favorably.

As the organic emission materials forming the organic emission, there can be used low-molecular-weight light emission materials. The low-molecular-weight light emission materials can include, for example, 9,10-diarylanthracene derivative, pyrene, coronene, rubrene, 1,1,4,4-tetraphenylbutadiene, tris(8-quinolate)aluminum complex,
tris(4-methyl-8-quinolate)aluminum complex,
bis(8-quinolate)zinc complex,
tris(4-methyl-5-trifluoromethyl-8-quinolate)aluminum complex,
tris(4-methyl-5-cyano-8-quinolate)aluminum complex,
bis(2-methyl-5-trifluoromethyl-8-quinolinolate) [4-(4-cyanophenyl)phenolate]aluminum complex,
bis(2-methyl-5-cyano-8-quinolinolate) [4-(4-cyanophenyl)phenolate]aluminum complex,
tris(8-quinolinolate)scandium complex,

bis[8-(para-tosyl)aminoquinoline]zinc complex or cadmium complex, 1,2,3,4-tetraphenylcyclopentadiene, coumarin series, perylene series, pyran series, anthrone series, porphyrin series, quinacridone series, N,N′-dialkyl substituted quinacridone series, naphthalimide series, N,N′-diaryl substituted pyrrolopyrrole series, iridium complex series. The present invention is not limited to these.

In addition, the organic emission materials can include polymer materials such as polyarylenes, polyarylenevinylenes or polyfluorenes.

The organic emission layer 104 can contain a matrix polymer. As the matrix polymers, there can be used favorably, for example, polycarbonate, polystyrene, polymethylmethacrylate, polypropylene, polyethersulfone, cycloolefin polymer, polyarylate, polyamide, polyethylene terephthalate or polyethylene naphthalate.

These organic emission materials are dissolved or dispersed stably in a solvent to form organic emission inks. As the solvents for dissolving or dispersing organic emission materials, there may be a single or a mixed solvent of toluene, xylene, acetone, anisole, methyl ethyl ketone, methyl isobutyl ketone, cyclohexanone and the like. Of these, aromatic organic solvent such as toluene, xylene or anisole are favorable in view of the solubility of the organic emission materials. Further, a surface acting agent, an antioxidant, a viscosity modifier, an ultraviolet absorber or the like may be added to the organic emission ink, as needed.

As the method for forming the organic emission layer 104, wet film-formation method are preferable. For pattern film formation, existing methods including wet film-formation methods or the like, such as an ink jet method, a nozzle printing method, a relief printing method, a gravure printing method or a screen printing method, may be used. Especially, a nozzle printing method or a relief printing method is preferred.

If there is no need for pattern film formation because such as of the unicolor organic EL devices or lighting devices, collective formation at the whole display region on the pixel electrode 207 can be carried out using simple methods such as a slit coat method, a spin coat method, a die coat method, a dipping method, a blade coat method or a spray method.

### <Electron-Injection Layer>

After forming the organic emission layer, the hole-blocking layer, the electron-injection layer and the like can be formed. The materials used in the hole-blocking layer and the electron-injection layer may be the ones generally used as electron-transport materials, can be formed by a vacuum vapor deposition method using a low-molecular-weight material such as of triazoles, oxazoles, oxadiazoles, siloles or boron series, a salt or an oxide of alkali metal or alkali earth metal, such as lithium fluoride or lithium oxide, or the like.

The electron-transport material or a mixture of the electron-transport material and a polymer such as polystyrene, polymethylmethacrylate or polyvinyl carbazole is dissolved or dispersed in a single or a mixed solvent of toluene, xylene, acetone, methyl ethyl ketone, methyl isobutyl ketone, cyclohexanone, methanol, ethanol, isopropyl alcohol, ethyl acetate, butyl acetate, water and the like to make an electron-injection coating liquid. The electron-injection coating liquid can be applied for film formation by a printing method.

### <Opposite Electrode>

Next, the opposite electrode (the second electrode) 106 is formed. If the opposite electrode is provided as a cathode, a low work function substance which has high electron-injection efficiency to the organic emission material is used. Specifically, a metal such as Mg, Al or Yb may be used alone. Alternatively, Li or a compound, such as Li oxide or LiF, of approximately 1 nm may be sandwiched by the interface contacting with the light emission medium layer, and Al or Cu having high stability and conductivity may be stacked thereon to be used. Also, in order to balance electron-injection efficiency and stability, there may be used an alloy of one or more types of metals having low work function, such as Li, Mg, Ca, Sr, La, Ce, Er, Eu, Sc, Y or Yb, and a stable metal element such as Ag, Al or Cu. Specifically, there can be used an alloy such as MgAg, AlLi or CuLi.

As the methods for forming the opposite electrode 106, there can be used a resistance heating vapor deposition method, an electron beam vapor deposition method, a reactive vapor deposition method, an ion plating method or a sputtering method, depending on the materials.

### <Sealing>

The organic EL display device can emit light by sandwiching the light emission material between the electrodes and applying a current thereto. However, since the organic emission material is easily deteriorated by moisture or oxygen in the atmosphere, it is generally sealed to isolate from the outside.

### <Can Sealing>

In sealing, for example, a sealing can may be bonded on the substrate. The sealing can needs to have low gas permeability. As its material, there can be used glass, a metal such as stainless steel, or the like. As the adhesive agent, UV curing adhesive agent is preferable.

### <Passivation Layer>

For protecting the organic EL device against oxygen or moisture from the outside, a passivation layer may be formed on the opposite electrode. As the passivation layer, there may be used metal oxide such as silicon oxide or aluminum oxide, metal fluoride such as aluminum fluoride or magnesium fluoride, metal nitride such as silicon nitride, aluminum nitride or carbon nitride, metal oxynitride such as silicon oxynitride, metal carbide such as silicon carbide, or as needed, a laminate of polymer resin film, such as acrylic resin, epoxy resin, silicon resin or polyester resin, thereon. Especially, in view of barrier property and transparency, it is preferred to use silicon oxide, silicon oxynitride or silicon nitride. Moreover, if a laminate or a gradient film in which the film density is changed is used, the film has both step coverage property and barrier property.

As the methods for forming the passivation layer, depending on materials, there can be used a resistance heating vapor deposition method, an electron beam vapor deposition method, a reactive vapor deposition method, an ion plating method, a sputtering method and a CVD method. Especially, a CVD method is preferred in view of barrier property and step coverage property, further since the film density or the film composition can be changed easily by film forming conditions. As CVD methods, there can be used a thermal CVD method, a plasma CVD method, a catalyst CVD method, a VUV-CVD method or the like. As reactive gases used for CVD methods, to organic silicon compound such as silane, hexamethyldisilazane (HMDS) or tetraethoxysilane, a gas such as N₂, O₂, NH₃, H₂ or N₂O may be added as needed. Further, as needed, the film density may be changed by changing gas flow rate such as of silane, or plasma power. Also, hydrogen or carbon may be formulated depending on the reactive gas to be used.

The thickness of the passivation layer is preferably set at 5 μm or less, more preferably 1 μm or less.

### <Sealing Body>

For sealing, a resin layer can be provided on a sealing base to stick them together.

The sealing base needs to be a base having low permeability of moisture or oxygen. An example of materials can include ceramics such as alumina, silicon nitride or boron nitride, glass such as alkali-free glass or alkali glass, silica and moisture-proof films. An example of the moisture-proof films can include a film where SiOₓ is formed on both surfaces of a plastic substrate by a CVD method, a laminated film of a film having a low permeability and a water-absorbing film or a coating water-absorbing agent. It is preferred that the moisture transmission of the moisture-proof film is 10⁻⁶ g/m²/day or less.

An example of the materials of the resin layer can include light curing adhesive resin such as epoxy resins, acrylic resins or silicon resin, thermosetting adhesive resin, two-liquid curing adhesive resin, acrylic resins such as ethylene-ethyl acrylate (EEA) polymer, vinyl resins such as ethylene-vinyl acetate (EVA), thermoplastic resin such as polyamide or synthetic rubber, and thermoplastic adhesive resin such as polyethylene or acid denaturation products of polypropylene.

An example of the methods for forming the resin layer on the sealing base can include a solvent solution method, an extrusion laminating method, a melting/hot-melt method, a calendaring method, a nozzle coating method, a screen printing method, a vacuum laminating method, and a heat roll laminating method. As needed, hygroscopic or oxygen-absorbing materials can be contained. The thickness of the resin layer formed on the sealing base is preferably approximately 5-500 μm, while it is arbitrarily determined depending on the size or the shape of the organic EL display device to be sealed. It will be noted that the resin layer is formed on the sealing base here, but can be formed directly on the organic EL device side.

Finally, the organic EL display device and the sealing body are stuck together in a sealing chamber. If the sealing body is made a two-layered structure and the thermoplastic resin is used for the resin layer, it is preferred that only pressure bonding with a heated roll is carried out. If the thermosetting adhesive resin is used, it is preferred that pressure bonding with a heated roll is carried out, and thereafter heat curing is performed at a curing temperature. If the light curing adhesive resin is used, it can cure by irradiating light after pressure bonding with the roll.

### Example 1

Examples of the present invention are now described.

As the substrate 100, a glass which is 0.7 mm in thickness and 40 mm square was used. On this, ITO serving as the first electrode (anode) 101 was formed to be 150 nm in thickness by sputtering, followed by subjecting to patterning to be lineal. Subsequently, a separator wall pattern was formed to be a shape having an opening which is 2 mm square on the ITO line.

Next, as the hole-injection layer 102, a mixture of poly(3,4-ethylenedioxythiophene) and polystyrene sulfonate was formed to be 60 nm in thickness by a spin coating method.

Subsequently, the hole-transport layer 103 was formed. An ink was used to coat by a spin coating method. The ink is made by mixing TPT1 shown in Chem. 2, which was the hole-transport material, and polystyrene having weight-average molecular weight of 200 thousand by a ratio of 7:3, thereafter dissolving in toluene. The thickness after drying the solvent was 20 nm.

Next, the organic emission layer was formed. An ink was used to coat by a blade coat method. The ink is made by mixing 2,2′,2″-(1,3,5-benzenetriyl)tris(1-phenyl-1H-benzimidazole) (TPBi) as a host agent and tris(2-(p-tolyl)pyridine)iridiumIII (Ir(mppy)3) as a doping agent by a ratio of 94:6, thereafter dissolving in toluene. The substrate was heated at 70° C. during coating. The thickness after drying the solvent was 60 nm.

Subsequently, as the electron-transport layer 105, TPBi was formed to be 20 nm in thickness by a vacuum vapor deposition method. Next, as the second electrode (cathode) 106, LiF of 0.5 nm was formed by a vacuum vapor deposition, followed by forming aluminum film of 150 nm. A lineal metal mask for forming the layers in the opening of the separator wall pattern on the ITO line was used, the metal mask was provided to intersect with the ITO line, thereafter forming the layers. Thus, an organic EL light emission region was formed in the opening of the separator wall pattern.

After that, in order to protect these organic EL configuration body against external oxygen and hydrogen, they were sealed using glass caps and an adhesive agent. When the organic EL device obtained as above was operated, green light was emitted. The maximum luminous efficiency was 32 cd/A.

### Example 2

An organic EL device was prepared in the same manner as Example 1, except that polystyrene having weight-average molecular weight of 500 thousand was used for the hole-transport layer. When the obtained organic EL device was operated, green light was emitted, and the maximum luminous efficiency was 33 cd/A.

### Example 3

An organic EL device was prepared in the same manner as Example 1, except that polystyrene having weight-average molecular weight of a million was used for the hole-transport layer. When the obtained organic EL device was operated, green light was emitted, and the maximum luminous efficiency was 39 cd/A.

### Example 4

An organic EL device was prepared in the same manner as Example 1, except that polystyrene having weight-average molecular weight of 2 million was used for the hole-transport layer. When the obtained organic EL device was operated, green light was emitted, and the maximum luminous efficiency was 41 cd/A.

### Example 5

For forming the organic emission layer, an ink made by mixing 2,2′,2″-(1,3,5-benzenetriyl)tris(1-phenyl-1H-benzimidazole) (TPBi) as a host agent, tris(2-(p-tolyl)pyridine)iridiumIII (Ir(mppy)3) as a doping agent, and polystyrene having weight-average molecular weight of a million by a ratio of 75.2:4.8:20, thereafter dissolving in toluene was used. Except for that, an organic EL device was prepared in the same manner as Example 3. When the obtained organic EL device was operated, green light was emitted. The maximum luminous efficiency was 45 cd/A.

### Example 6

An organic EL device was prepared in the same manner as Example 3, except that the substrate was not heated during coating with the organic emission layer. When the obtained organic EL device was operated, green light was emitted, and the maximum luminous efficiency was 29 cd/A.

### Example 7

An organic EL device was prepared in the same manner as Example 1, except that polystyrene having weight-average molecular weight of 7 million was used for the hole-transport layer. When the obtained organic EL device was operated, green light was emitted, and the maximum luminous efficiency was 41 cd/A.

### Example 8

An organic EL device was prepared in the same manner as Example 1, except that polystyrene having weight-average molecular weight of 20 million was used for the hole-transport layer. When the obtained organic EL device was operated, green light was emitted, and the maximum luminous efficiency was 38 cd/A.

### Example 9

An organic EL device was prepared in the same manner as Example 1, except that polystyrene having weight-average molecular weight of 30 million was used for the hole-transport layer. When the obtained organic EL device was operated, green light was emitted, and the maximum luminous efficiency was 39 cd/A.

### Comparative Example 1

An organic EL device was prepared in the same manner as Example 1, except that the hole-transport layer was formed by coating using an ink made by dissolving TPT1 which is the hole-transport material in toluene. When the obtained organic EL device was operated, green light was emitted, but the maximum luminous efficiency was low, 17 cd/A.

### Comparative Example 2

An organic EL device was prepared in the same manner as Example 1, except that polystyrene having weight-average molecular weight of 10 thousand was used for the hole-transport layer. When the obtained organic EL device was operated, green light was emitted, but the maximum luminous efficiency was low, 17 cd/A.

### Comparative Example 3

An organic EL device was prepared in the same manner as Example 1, except that polystyrene having weight-average molecular weight of 100 thousand was used for the hole-transport layer. When the obtained organic EL device was operated, green light was emitted, but the maximum luminous efficiency was low, 22 cd/A.

### Comparative Example 4

An organic EL device was prepared in the same manner as Example 1, except that polystyrene having weight-average molecular weight of 15 thousand was used for the hole-transport layer. When the obtained organic EL device was operated, green light was emitted, but the maximum luminous efficiency was low, 22 cd/A.

### Comparative Example 5

An organic EL device was prepared in the same manner as Example 3, except that the substrate was heated at 130° C. which was larger than the boiling point, 110° C., of toluene, the solvent used in the ink configuring the organic emission layer, during forming the organic emission layer by coating. When the obtained organic EL device was operated, green light was emitted. The maximum luminous efficiency was 25 cd/A. The light emission was non-uniform. This was attributed to the reason that the organic emission layer was a non-uniform film.

Table 1 shows each maximum luminous efficiency.

TABLE 1

| | Weight-average molecular | | | During coat | |
|---|---|---|---|---|---|
| | weight of matrix polymer | | | of organic | |
| | | | Organic | emission layer, | |
| | Hole-transport | | emission | substrate heat | Luminous |
| | layer 30% | | layer 20% | temperature | efficiency |
| Example 1 | 200 | thousand | — | 70° C. | 32 cd/A |
| Example 2 | 500 | thousand | — | 70° C. | 33 cd/A |
| Example 3 | 1 | million | — | 70° C. | 39 cd/A |
| Example 4 | 2 | million | — | 70° C. | 41 cd/A |
| Example 5 | 1 | million | 1 million | 70° C. | 45 cd/A |
| Example 6 | 1 | million | — | No | 29 cd/A |
| Example 7 | 7 | million | — | 70° C. | 41 cd/A |
| Example 8 | 20 | million | — | 70° C. | 38 cd/A |
| Example 9 | 30 | million | — | 70° C. | 39 cd/A |
| Comparative | — | | — | 70° C. | 17 cd/A |
| example 1 | | | | | |
| Comparative | 10 | thousand | — | 70° C. | 17 cd/A |
| example 2 | | | | | |
| Comparative | 100 | thousand | — | 70° C. | 22 cd/A |
| example 3 | | | | | |
| Comparative | 150 | thousand | — | 70° C. | 23 cd/A |
| example 4 | | | | | |
| Comparative | 1 | million | — | 130° C. | 25 cd/A |

example 5

Examples using polystyrene having weight-average molecular weight of 200 thousand were able to obtain the luminous efficiency of 32 cd/A or more, further the luminous efficiency became larger as the weight-average molecular weight was increased.

### REFERENCE SIGNS LIST

100 . . . substrate
101 . . . pixel electrode (first electrode)
102 . . . hole-injection layer
103 . . . hole-transport layer
104 . . . organic emission layer
105 . . . electron-transport layer
106 . . . opposite electrode (second electrode)
200 . . . substrate
201 . . . active layer
202 . . . gate insulator layer
203 . . . source electrode
204 . . . drain electrode
205 . . . gate electrode
206 . . . insulator film
207 . . . pixel electrode (first electrode)
208 . . . separator wall
209 . . . scanning line
300 . . . organic EL display device
301 . . . pixel
302 . . . subpixel

What is claimed is:

1. An organic electroluminescent device, comprising:
a first electrode formed on a substrate, a light emission medium layer having at least an organic emission layer, and a second electrode formed to face the first electrode with the light emission medium layer sandwiched therebetween;
wherein the light emission medium layer has at least an organic emission layer and a hole-transport layer adjacent to the organic emission layer; and
wherein the hole-transport contains at least a low-molecular weight hole-transport material and a matrix polymer having insulation properties and weight-average molecular weight of from not smaller than about 200 thousand to not larger than about 50 million.

2. The organic electroluminescent device of claim 1, further comprising a separator wall formed to separate a light emission region.

3. The organic electroluminescent device of claim 1, wherein the weight-average molecular weight of the matrix polymer having insulation properties is from not smaller than about 1 million to not larger than about 50 million.

4. The organic electroluminescent device of claim 1, wherein the organic emission layer contains at least a low-molecular-weight light emission material and a matrix polymer having insulation properties and weight-average molecular weight of from not smaller than about 200 thousand to not larger than about 50 million.

5. The organic electroluminescent device of claim 4, wherein the organic emission layer contains at least the low-molecular-weight light emission material and the matrix polymer having insulation properties and weight-average molecular weight of from not smaller than about 1 million to not larger than about 50 million.

6. The organic electroluminescent device of claim 1, wherein the hole-transport layer and the organic emission layer contain the same type of the matrix polymer having insulation properties.

7. The organic electroluminescent device of claim 1, further comprising that the hole-transport layer and the organic emission layer are formed by a coating method.

8. The organic electroluminescent device of claim 7, further comprising that the substrate is heated in a step where the organic emission layer is formed by coating.

9. The organic electroluminescent device of claim 8, wherein a temperature for heating the substrate is equal to or smaller than the boiling point of an solvent of an ink forming the organic emission layer.

10. The organic electroluminescent device of claim 7, wherein the step for applying the organic emission layer is by a nozzle printing method.

11. The organic electroluminescent device of claim 7, wherein the step for applying the organic emission layer is by a relief printing method.
